(19) United States
(12) Patent Application Publication
(10) Pub. No.: US 2024/0387564 A1
(43) Pub. Date: Nov. 21, 2024

(54) ARRAY SUBSTRATE AND DISPLAY

(71) Applicant: Sharp Display Technology Corporation, Kameyama City, Mie (JP)

(72) Inventors: Tomoyuki NISHIHAMA, Kameyama City, Mie (JP); Yoshimizu MORIYA, Kameyama City, Mie (JP)

(21) Appl. No.: 18/429,627

(22) Filed: Feb. 1, 2024

(30) Foreign Application Priority Data
Feb. 28, 2023 (JP) 2023-029354

(51) Int. Cl. H01L 27/12; G02F 1/1368

(52) U.S. Cl. CPC H01L 27/1244; G02F 1/13685

(57) ABSTRACT

An array substrate includes: a first electrode; a first insulating film disposed on an upper layer side of the first electrode; a second electrode disposed on an upper layer side of the first insulating film; a second insulating film disposed on an upper layer side of the second electrode; and a third electrode disposed on an upper layer side of the second insulating film, at least a part of the third electrode doesn't overlap the first electrode, the second electrode has a first overlapping portion that overlaps the first electrode and a second overlapping portion that doesn't overlap the first electrode and overlaps the third electrode, the first insulating film has a first contact hole at a position overlapping the first electrode and the first overlapping portion, and the second insulating film has a second contact hole at a position overlapping the second overlapping portion and the third electrode.

### BACKGROUND

### 1. Field

The present disclosure relates to an array substrate and a display.

### 2. Description of the Related Art

As an example of an array substrate provided in a display in the related art, one described in International Publication No. 2018/190214 below is known. The array substrate described in International Publication No. 2018/190214 includes a TFT having a drain electrode made of a third metal film; a pixel electrode made of a first transparent electrode film; a pixel contact hole that opens at a position overlapping the drain electrode and the pixel electrode in a flattening film, a third interlayer insulating film, and a fourth interlayer insulating film; a touch wiring made of a fourth metal film; a wiring coupling portion made of the first transparent electrode film; a first wiring contact hole that opens at a position overlapping a touch wiring and a wiring coupling portion in the fourth interlayer insulating film; a touch lead-out wiring made of a third metal film; and a second wiring contact hole that opens at a position overlapping the wiring coupling portion and the touch lead-out wiring in the flattening film, the third interlayer insulating film, and the fourth interlayer insulating film.

In the array substrate described in International Publication No. 2018/190214 described above, the pixel contact hole connecting the drain electrode and the pixel electrode is provided in a shape that penetrates the flattening film, the third interlayer insulating film, and the fourth interlayer insulating film. Here, an electrode coupled to both of the drain electrode and the pixel electrode may be provided by using the fourth metal film interposed between the third interlayer insulating film and the fourth interlayer insulating film. In that case, the pixel contact hole includes a first contact hole formed in the flattening film and the third interlayer insulating film, and a second contact hole formed in the fourth interlayer insulating film. The electrode made of the fourth metal film and the drain electrode, which are described above, are coupled to each other through the first contact hole, and the electrode made of the fourth metal film and the pixel electrode are coupled to each other through the second contact hole.

With such a configuration, after providing the electrode made of the fourth metal film, the second contact hole is formed in the fourth interlayer insulating film in the first contact hole. Since the second contact hole is formed at a position recessed by the film thickness of the flattening film and the third interlayer insulating film from the outermost surface of the fourth interlayer insulating film, there is a problem in that it is difficult to form the second contact hole in the fourth interlayer insulating film as designed. For example, a level difference may occur at the opening edge of the second contact hole in the fourth interlayer insulating film, and due to the level difference, a film break may occur in the pixel electrode, or the second contact hole may not be formed. As a result, the coupling reliability between the electrode made of the fourth metal film and the pixel electrode may decrease.

It is desirable to improve a coupling reliability.

### SUMMARY

According to an aspect of the disclosure, there is provided an array substrate including: a first electrode made of a first conductive film; a first insulating film disposed on an upper layer side of the first electrode; a second electrode made of a second conductive film disposed on an upper layer side of the first insulating film; a second insulating film disposed on an upper layer side of the second electrode; and a third electrode made of a third conductive film disposed on an upper layer side of the second insulating film, in which at least a part of the third electrode does not overlap the first electrode, the second electrode has a first overlapping portion that overlaps the first electrode and a second overlapping portion that does not overlap the first electrode and overlaps the third electrode, the first insulating film has a first contact hole disposed at a position overlapping the first electrode and the first overlapping portion, and the second insulating film has a second contact hole disposed at a position overlapping the second overlapping portion and the third electrode.

According to another aspect of the present disclosure, there is provided a display including: the array substrate according to the above aspect; and a counter substrate disposed to face the array substrate.

### BRIEF DESCRIPTION OF THE DRAWINGS

FIG. 1 is a plan view of a liquid crystal panel according to Embodiment 1.

FIG. 2 is a circuit diagram illustrating a pixel array in a display area of an array substrate provided in the liquid crystal panel according to Embodiment 1.

FIG. 3 is a plan view illustrating the vicinity of a TFT and a pixel electrode in a display area of the liquid crystal panel according to Embodiment 1.

FIG. 4 is a cross-sectional view in the liquid crystal panel according to Embodiment 1 taken along the line iv-iv in FIG. 3.

FIG. 5 is a cross-sectional view in the liquid crystal panel according to Embodiment 1 taken along the line v-v in FIG. 3.

FIG. 6 is an enlarged cross-sectional view of a coupling structure between a drain electrode and a pixel electrode in FIG. 5 in the liquid crystal panel according to Embodiment 1.

FIG. 7 is a cross-sectional view illustrating a coupling part between a touch electrode and a touch wiring in the liquid crystal panel according to Embodiment.

FIG. 8 is a cross-sectional view of the same range as those of FIGS. 6 and 7, illustrating a state where a photoresist film is exposed via a photomask through an exposure process of a ninth process included in a method for manufacturing the array substrate according to Embodiment 1.

FIG. 9 is a cross-sectional view of the same range as those of FIGS. 6 and 7, illustrating a state where a photoresist film is developed through a development process of the ninth process included in the method for manufacturing the array substrate according to Embodiment 1.

FIG. 10 is a cross-sectional view of the same range as those of FIGS. 6 and 7, illustrating a state where a flattening film and a second interlayer insulating film are etched through a first etching process and an ashing process of the ninth process included in the method for manufacturing the array substrate according to Embodiment 1, and a thin film portion is ashed.

FIG. 11 is a cross-sectional view of the same range as those of FIGS. 6 and 7, illustrating a state where a second interlayer insulating film is etched through a second etching process of the ninth process included in the method for manufacturing the array substrate according to Embodiment 1.

FIG. 12 is a plan view illustrating the vicinity of a TFT and a pixel electrode in a display area of a liquid crystal panel according to Embodiment 2.

FIG. 13 is a cross-sectional view of the liquid crystal panel according to Embodiment 2 taken along the line xiii-xiii in FIG. 12.

### DESCRIPTION OF THE EMBODIMENTS

### Embodiment 1

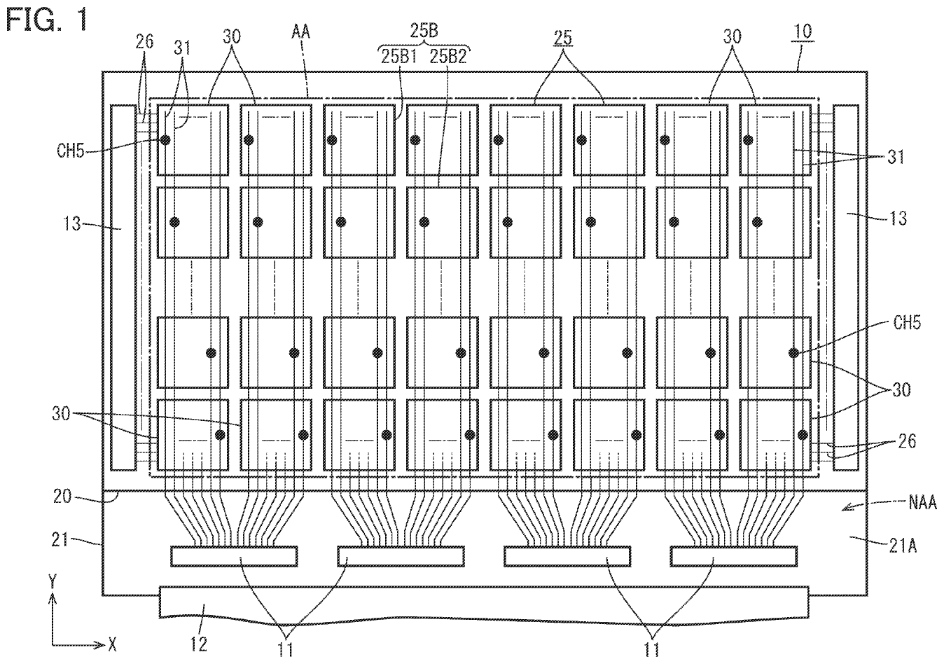

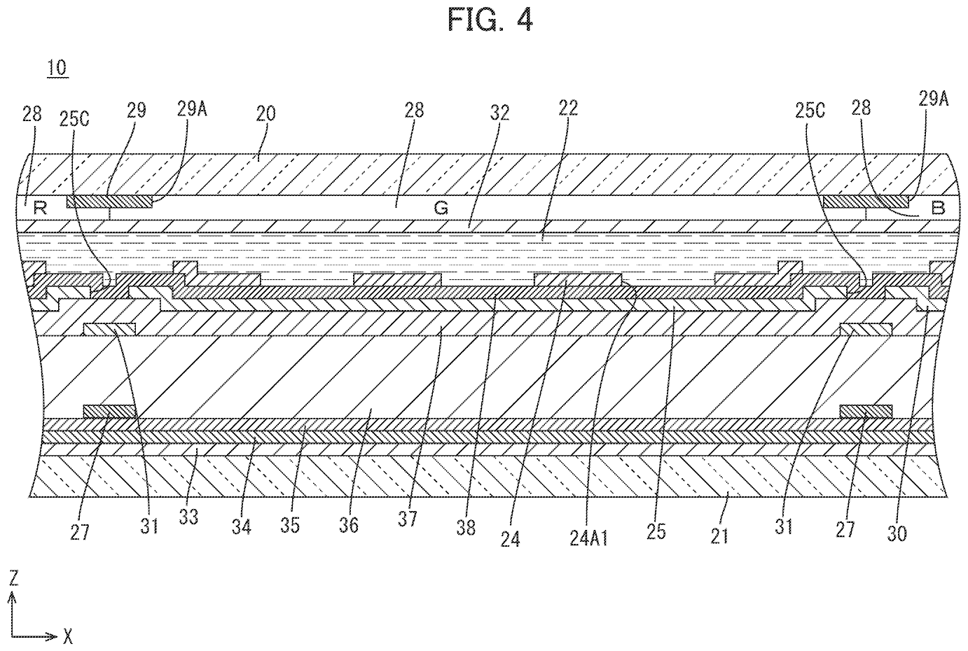

Embodiment 1 will be described with reference to FIGS. 1 to 11. In the present embodiment, a liquid crystal panel (display) 10 having an image display function and a touch panel function (position input function, position detection function) will be illustrated. The X-axis, Y-axis, and Z-axis are shown in a part of each drawing, and the direction of each axis is drawn in the direction shown in each drawing. Upper sides of FIGS. 4 to 11 are defined as a front side, and lower sides of the same drawing is defined as a back side.

A schematic planar configuration of the liquid crystal panel 10 will be described with reference to FIG. 1. As illustrated in FIG. 1, the liquid crystal panel 10 has a substantially rectangular planar shape that is horizontally long as a whole. In the liquid crystal panel 10, the short-side direction coincides with the Y-axis direction, the long-side direction coincides with the X-axis direction, and the plate thickness direction (normal direction of the principal surfaces of each of the substrates 20 and 21) coincides with the Z-axis direction, respectively. The liquid crystal panel 10 can be used, for example, in an in-vehicle liquid crystal display, or the like. The in-vehicle liquid crystal display is used, for example, in an instrument panel, a multifunctional display, an infotainment system, and the like. The liquid crystal panel 10 can display an image by using the illumination light emitted from the backlight device (illumination device) disposed on the back side of the liquid crystal panel 10. The backlight device is disposed on the back side (rear surface side) of the liquid crystal panel 10, and has a light source (for example, LED), an optical member that converts the light from the light source into planar light by applying an optical effect, and the like.

As illustrated in FIG. 1, the liquid crystal panel 10 has a display area (range surrounded by a one-dot chain line in FIG. 1) AA on which an image is displayed at a central part of a screen. On the other hand, a picture-frame-shaped (frame-like) outer peripheral part surrounding the display area AA on the screen of the liquid crystal panel 10 is defined as a non-display area NAA in which no image is displayed. The liquid crystal panel 10 is formed by bonding a pair of substrates 20 and 21. The substrate on the front side (front surface side) of the pair of substrates 20 and 21 is the counter substrate 20, and the substrate on the back side (rear surface side) is the array substrate (wiring substrate) 21. Both the counter substrate 20 and the array substrate 21 are formed by laminating various films on the inner surface side of a glass substrate. A polarizing plate is attached to each of the outer surface sides of both the substrates 20 and 21.

As illustrated in FIG. 1, the array substrate 21 includes a protruding portion 21A protruding laterally from the counter substrate 20 along the Y-axis direction. A driver (signal supply unit) 11 and a flexible substrate 12 for supplying various signals related to a display function and a touch panel function, which will be described below, are mounted on the protruding portion 21A. The driver 11 is mounted on the protruding portion 21A on the array substrate 21 by chip on glass (COG). The driver 11 is made of an LSI chip having a drive circuit therein, and processes various signals transmitted by the flexible substrate 12. The drivers 11 are disposed side by side in the display area AA on the array substrate 21 at intervals in the X-axis direction. The flexible substrate 12 has a configuration in which multiple wiring patterns are formed on a base material made of an insulating and flexible synthetic resin material (for example, polyimide resin or the like). One end side part of the flexible substrate 12 is coupled to the array substrate 21, and the other end side part is coupled to an external control substrate (signal supply source), respectively. Various signals supplied from the control substrate are transmitted to the liquid crystal panel 10 via the flexible substrate 12. In the non-display area NAA of the array substrate 21, a pair of gate circuit units 13 is provided to interpose the display area AA from both sides in the X-axis direction. The gate circuit unit 13 supplies a scanning signal to a gate wiring 26 which will be described later. The gate circuit unit 13 is monolithically provided on the array substrate 21.

The liquid crystal panel 10 according to the present embodiment has both a display function of displaying an image and a touch panel function of detecting the position (input position) where the user inputs based on the image to be displayed. The liquid crystal panel 10 is integrated (in-cell) with a touch panel pattern for exhibiting the touch panel function. This touch panel pattern is defined as a so-called projection electrostatic capacitance method, and a detection method thereof is defined as a self-capacitance method. As shown in FIG. 1, the touch panel pattern is configured to include a plurality of touch electrodes (position detection electrodes) 30 disposed side by side in a matrix shape in a principal surface of the liquid crystal panel 10. The touch electrodes 30 are disposed in the display area AA of the liquid crystal panel 10. Therefore, the display area AA of the liquid crystal panel 10 substantially coincides with the touch area (position input area) where the input position can be detected. The non-display area NAA substantially coincides with a non-touch area (non-position input area) where detection of the input position is not possible. Based on an image displayed in the display area AA of the liquid crystal panel 10, when the user approaches the front surface (display surface) of the liquid crystal panel 10 with a position input body such as the user's finger, which is a conductor, or a touch pen operated by the user, an electrostatic capacitance is formed between the position input body and the touch electrode 30. As a result, a change occurs in the electrostatic capacitance detected by the touch electrode 30 located near the position input body as the position input body approaches, and the electrostatic capacitance is different from the electrostatic capacitance of the touch electrode 30 located far from the position input body. A detection circuit described later can detect an input position based on this difference in electrostatic capacitance.

As illustrated in FIG. 1, the touch electrode 30 described above is configured by the common electrode 25 provided on the array substrate 21. The common electrode 25 is disposed to extend over substantially the entire area of the display area AA. The common electrode 25 includes a partition opening portion (partition slit) 25A having a substantial lattice shape, and is divided into a plurality of touch electrodes 30 by the partition opening portion 25A. The partition opening portion 25A includes a first partition opening portion 25A1 that crosses the entire length of the common electrode 25 substantially along the Y-axis direction and partitions between the touch electrodes 30 adjacent to each other in the X-axis direction, and a second partition opening portion 25A2 that traverses the entire length of the common electrode 25 along the X-axis direction and partitions between the touch electrodes 30 adjacent to each other in the Y-axis direction. A plurality of the first partition opening portions 25A1 are disposed side by side at intervals of the touch electrode 30 in the X-axis direction. A plurality of the second partition opening portions 25A2 are disposed side by side at intervals of the touch electrode 30 in the Y-axis direction. A plurality of touch electrodes 30 partitioned by the partition opening portion 25A are disposed side by side at intervals along the Y-axis direction and the X-axis direction in the display area AA. The touch electrode 30 has a substantially rectangular shape in a plan view, and the dimension of one side is approximately several millimeters. Therefore, the size of the touch electrode 30 is much larger than the size of a pixel described later in a plan view, and the touch electrodes 30 are disposed in a range spanning a plurality of (tens to several hundred) pixels in the X-axis direction and the Y-axis direction.

As illustrated in FIG. 1, a plurality of touch wirings (first wirings, position detection wirings) 31 provided on the liquid crystal panel 10 are selectively coupled to the plurality of touch electrodes 30. The touch wiring 31 extends along the Y-axis direction. One end side part of the touch wiring 31 in the Y-axis direction is coupled to the driver 11 in the non-display area NAA. The other end side part of the touch wiring 31 in the Y-axis direction is coupled to a specific touch electrode 30 among the plurality of touch electrodes 30 arranged along the Y-axis direction in the display area AA. The formation range of the touch wiring 31 in the Y-axis direction is limited to the range from the driver 11 to the touch electrode 30 to be coupled, and the touch wiring 31 is not disposed on the side (upper side in FIG. 1) opposite to the driver 11 side (lower side in FIG. 1) than the touch electrode 30 to be coupled. Depending on the number of the touch wirings 31 to be installed, only one touch wiring 31 may be coupled to one touch electrode 30, or a plurality of touch wirings 31 may be coupled to one touch electrode 30. The number of touch wirings 31 coupled to one touch electrode 30 may be different according to the position of the touch electrode 30. In that case, for example, it is preferable that the number of touch wirings 31 coupled to the touch electrode 30 far from the driver 11 is larger than the number of touch wirings 31 coupled to the touch electrode 30 close to the driver 11, and is not necessarily limited. In FIG. 1, the coupling location of the touch wiring 31 to the touch electrode 30 (touch contact hole CH5) is illustrated by a black circle. Furthermore, the touch wiring 31 is coupled to a detection circuit. The detection circuit may be provided in the driver 11, and may be provided outside the liquid crystal panel 10 via the flexible substrate 12.

As illustrated in FIG. 1, a common potential signal related to an image display function and a touch signal (position detection signal) related to a touch panel function are supplied from the driver 11 to the touch wiring 31 in a time division manner. The timing at which the common potential signal is supplied from the driver 11 to the touch wiring 31 is a display period. The timing at which the touch signal is supplied from the driver 11 to the touch wiring 31 is a sensing period (position detection period). This common potential signal is transmitted to all the touch wirings 31 at the same timing (display period), and thus all the touch electrodes 30 have a reference potential based on the common potential signal and function as the common electrode 25.

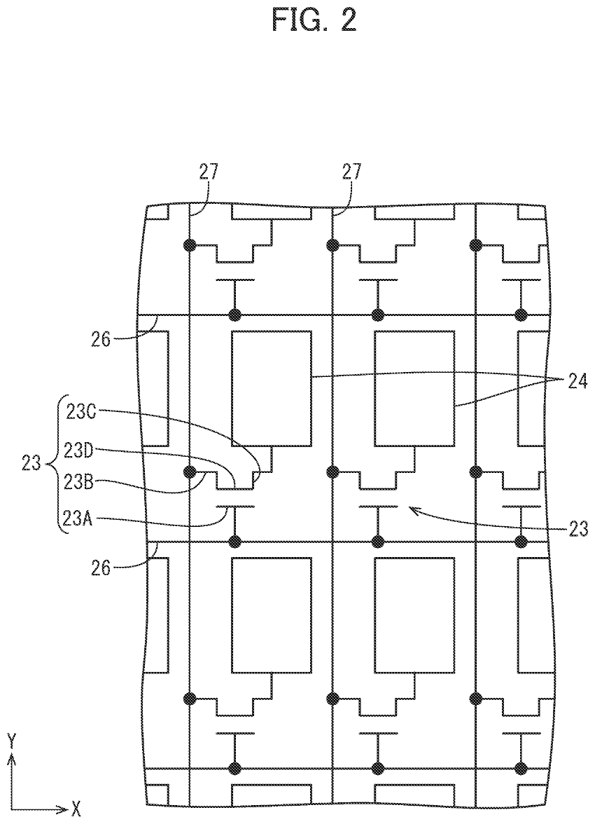

An outline of a pixel array in the display area AA on the array substrate 21 will be described with reference to FIG. 2. As illustrated in FIG. 2, a thin film transistor (switching element, TFT) 23 and a pixel electrode (third electrode) 24 are provided on the inner surface side of the display area AA on the array substrate 21. A plurality of TFTs 23 and a plurality of pixel electrodes 24 are provided side by side in a matrix shape at intervals along the X-axis direction and the Y-axis direction. Around these TFTs 23 and pixel electrodes 24, a plurality of gate wirings (scanning wiring) 26 and a plurality of source wirings (second wiring, signal wiring, data wiring) 27 that are orthogonal (intersect) to each other are disposed. The gate wiring 26 extends along the X-axis direction and crosses the display area AA. A plurality of gate wirings 26 are disposed side by side at intervals in the Y-axis direction. The source wiring 27 extends along the Y-axis direction and traverses the display area AA. A plurality of source wirings 27 are disposed side by side at intervals in the X-axis direction. The TFT 23 and the pixel electrode 24 are disposed near an intersection part between the gate wiring 26 and the source wiring 27. The pixel electrode 24, the gate wiring 26, and the source wiring 27 are coupled to the TFT 23. The TFT 23 includes a gate electrode 23A coupled to the gate wiring 26, a source electrode 23B coupled to the source wiring 27, a drain electrode (first electrode) 23C coupled to the pixel electrode 24, and a semiconductor portion 23D coupled to the source electrode 23B and the drain electrode 23C. The semiconductor portion 23D is made of a semiconductor material and is disposed to overlap the gate electrode 23A. When the TFT 23 is driven based on the scanning signal supplied from the gate wiring 26 to the gate electrode 23A, the TFT 23 charges the pixel electrode 24 to a potential based on the image signal supplied from the source wiring 27 to the source electrode 23B. The pixel electrode 24 has a longitudinal shape with the Y-axis direction as a longitudinal direction.

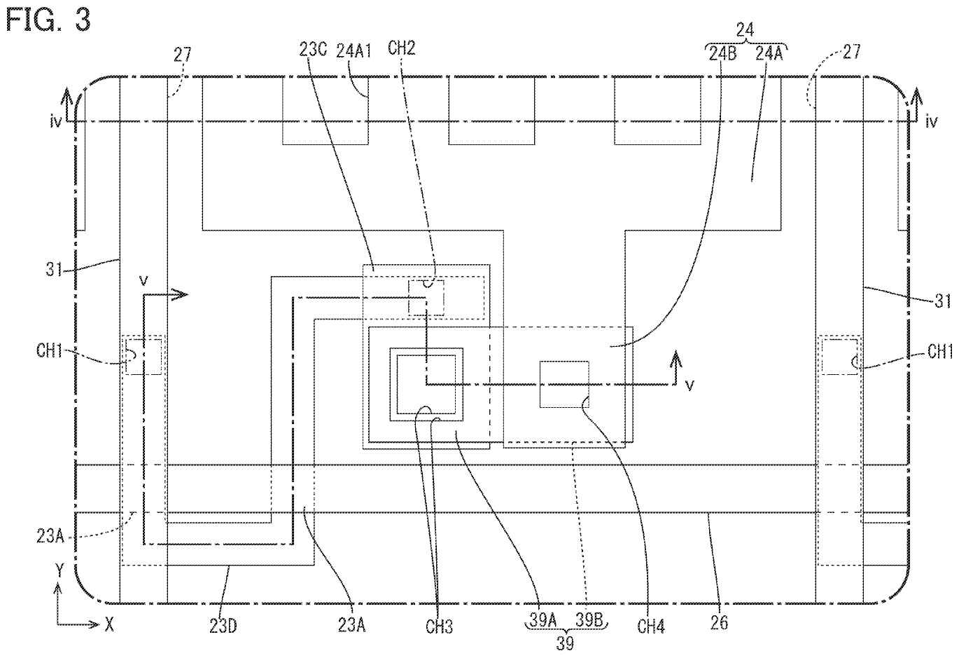

A specific planar configuration of the vicinity of the TFT 23 in the display area AA of the array substrate 21 will be described with reference to FIG. 3. As illustrated in FIG. 3, the pixel electrode 24 includes a vertically long pixel electrode body 24A and a contact portion 24B continuous with one end portion of the pixel electrode body 24A in the Y-axis direction. In the pixel electrode body 24A, the longitudinal direction coincides with the Y-axis direction (extending direction of the source wiring 27), and the lateral direction orthogonal to the longitudinal direction coincides with the X-axis direction (extending direction of the gate wiring 26). A plurality of (three in FIG. 3) slits 24A1 extending along a side edge on the longitudinal side are formed in the pixel electrode body 24A. The specific number of installation, shape, formation range, and the like of the slits 24A1 can be appropriately changed other than those illustrated in the drawing. The contact portion 24B extends downward in FIG. 3 from the pixel electrode body 24A. The contact portion 24B has a narrower and vertically longer rectangular shape than the pixel electrode body 24A in a plan view. Substantially the entire area of the pixel electrode 24 does not overlap the drain electrode 23C of the TFT 23 in a plan view. The touch wiring 31 is disposed to overlap the source wiring 27 in a plan view.

As illustrated in FIG. 3, the gate electrode 23A constituting the TFT 23 includes a part of the gate wiring 26, specifically, a part overlapping the semiconductor portion 23D, which will be described later, in a plan view. The source electrode 23B includes a part of the source wiring 27. Specifically, a part of the source wiring 27 that overlaps a part of the semiconductor portion 23D in a plan view and is coupled to the semiconductor portion 23D is the source electrode 23B. The drain electrode 23C has a vertically long rectangular shape in a plan view, and is disposed at a position at an interval from the source electrode 23B in the X-axis direction. A part of the drain electrode 23C (upper part in FIG. 3) overlaps a part of the semiconductor portion 23D in a plan view and is coupled to the semiconductor portion 23D. A part of the drain electrode 23C (lower part in FIG. 3) is coupled to the contact portion 24B of the pixel electrode 24 via a first intermediate electrode (second electrode) 39 described later. The detailed configuration of the first intermediate electrode 39 will be described later.

As illustrated in FIG. 3, the semiconductor portion 23D is routed to be bent multiple times (three times) in the middle of running from the source electrode 23B to the drain electrode 23C. The semiconductor portion 23D has one end portion that overlaps the source electrode 23B in a plan view and is coupled to the source electrode 23B, and the other end portion that overlaps the drain electrode 23C in a plan view and is coupled to the drain electrode 23C. The semiconductor portion 23D includes a first portion that includes one end portion, extends along the Y-axis direction to overlap the source wiring 27, and crosses the gate wiring 26; and a second portion that is bent from the first portion and extends along the X-axis direction toward the drain electrode 23C side to be coupled (right side in FIG. 3). The semiconductor portion 23D includes a third portion that is bent from the second portion described above, extends along the Y-axis direction, and crosses the gate wiring 26 again. The semiconductor portion 23D includes a fourth portion that is bent from the third portion described above, extends along the X-axis direction, and includes the other end portion. As described above, in the semiconductor portion 23D, the intermediate part positioned between the one end portion and the other end portion has a folded shape, and intersects the gate wiring 26 twice. Therefore, the gate wiring 26 has two overlapping parts, that is, two gate electrodes 23A for one semiconductor portion 23D. One TFT 23 includes two gate electrodes 23A.

A cross-sectional configuration of the display area AA of the liquid crystal panel 10 will be described with reference to FIG. 4. As illustrated in FIG. 4, the liquid crystal panel 10 includes a liquid crystal layer (medium layer) 22 disposed between the pair of substrates 20 and 21 and containing liquid crystal molecules which are substances of which optical characteristic change with application of an electric field. In the display area AA on the inner surface side of the counter substrate 20 constituting the liquid crystal panel 10, three color filters 28 of blue (B), green (G), and red (R) are provided. A plurality of color filters 28 having colors different from each other are disposed side by side to be adjacent to each other in the extending direction (X-axis direction) of the gate wiring 26. A plurality of color filters 28 having colors different from each other extend along the extending direction (Y-axis direction) of the source wiring 27 and the touch wiring 31. As described above, the plurality of color filters 28 having colors different from each other are arranged in vertical stripes as a whole. These color filters 28 are disposed to overlap each pixel electrode 24 on the array substrate 21 side in a plan view. The color filter 28 and the pixel electrode 24 overlapping each other constitute a pixel which is a display unit. A plurality of color filters 28 having colors different from each other are disposed such that their boundaries (color boundaries) overlap the source wiring 27 and the touch wiring 31.

In the display area AA on the inner surface side of the counter substrate 20, a light shielding portion 29 is provided as illustrated in FIG. 4. The light shielding portion 29 has a substantially lattice planar shape to partition between the pixel electrodes 24 adjacent to each other, and has a pixel opening portion 29A at a position overlapping most of the pixel electrodes 24 in a plan view. It is possible to emit the transmitted light of the pixel electrode 24 to the outside of the liquid crystal panel 10 by the pixel opening portion 29A. The light shielding portion 29 is disposed to overlap at least the TFT 23, the gate wiring 26, the source wiring 27, and the touch wiring 31 on the array substrate 21 side in a plan view. In addition, an overcoat film 32 disposed in a solid pattern over substantially the entire area of the counter substrate 20 for flattening is provided on the upper layer side (liquid crystal layer 22 side) of the color filter 28. An alignment film for aligning the liquid crystal molecules contained in the liquid crystal layer 22 is formed on the innermost surface (uppermost surface) of both of the substrates 20 and 21, which is in contact with the liquid crystal layer 22, respectively.

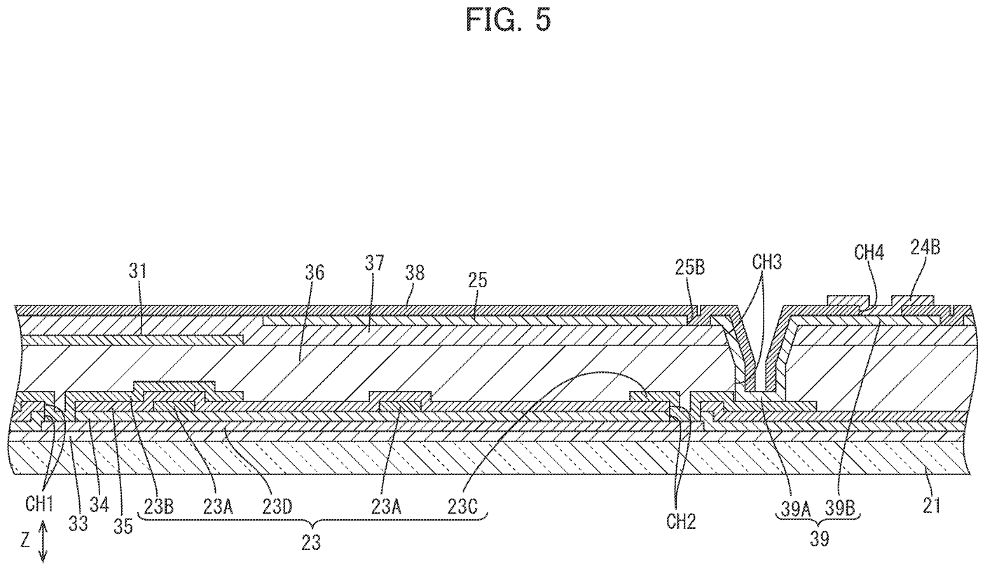

Here, various films laminated on the inner surface side of the array substrate 21 will be described with reference to FIG. 5. FIG. 5 is a cross-sectional view (sectional view taken along the line v-v in FIG. 3) of the array substrate 21 cut along the semiconductor portion 23D. As illustrated in FIG. 5, on the glass substrate of the array substrate 21, in order from the lower layer side (glass substrate side), at least a base coat film 33, a semiconductor film, a gate insulating film 34, a first metal film, a first interlayer insulating film 35, a second metal film (first conductive film), a flattening film (first insulating film, lower insulating film) 36, a third metal film (fourth conductive film), a second interlayer insulating film (first insulating film, upper insulating film) 37, a first transparent electrode film (second conductive film), a third interlayer insulating film (second insulating film) 38, a second transparent electrode film (third conductive film), and an alignment film are formed in a laminated manner.

The semiconductor film is made of a continuous grain silicon (CG) thin film which is a type of polycrystalline silicon thin film (polycrystalline silicon thin film). The CG silicon thin film is formed, for example, by adding a metal material to an amorphous silicon thin film and performing a short-time heat treatment at a low temperature of about 550° C. or less, and accordingly, continuousness is achieved in the atomic arrangement at the crystal grain boundary of the silicon crystal. Each of the first metal film, the second metal film, and the third metal film has conductivity and light shielding properties by being a single layer film made of one type of metal material selected from copper, titanium, aluminum, molybdenum, tungsten, and the like, or a laminated film made of different types of metal materials or alloy. The first metal film constitutes the gate wiring 26, the gate electrode 23A of the TFT 23, and the like. The second metal film constitutes the source wiring 27, the source electrode 23B and the drain electrode 23C of the TFT 23, and the like. The third metal film constitutes the touch wiring 31 and the like. The first transparent electrode film and the second transparent electrode film are made of a transparent electrode material, such as indium tin oxide (ITO) or indium zinc oxide (IZO)). The film thicknesses of the first transparent electrode film and the second transparent electrode film are, for example, approximately 50 nm to 200 nm. The first transparent electrode film constitutes the common electrode 25 (touch electrode 30), the first intermediate electrode 39, and the like. The second transparent electrode film constitutes the pixel electrode 24 and the like.

The base coat film 33, the gate insulating film 34, the first interlayer insulating film 35, the second interlayer insulating film 37, and the third interlayer insulating film 38 are respectively made of an inorganic insulating material (inorganic material) such as SiO₂ (silicon oxide, silicon oxide) or SiNₓ (silicon nitride). The film thicknesses of the base coat film 33, the gate insulating film 34, the first interlayer insulating film 35, the second interlayer insulating film 37, and the third interlayer insulating film 38, which are made of an inorganic insulating material, are, for example, approximately 100 nm to 300 nm. In the present embodiment, the film thickness of the second interlayer insulating film 37 is larger than the film thicknesses of the other insulating films 33, 34, 35, and 38 made of an inorganic insulating material. The flattening film 36 is made of, for example, an organic insulating material (organic material) such as PMMA (acrylic resin), and has a larger film thickness than film thicknesses of the other insulating films 33, 34, 35, 37, and 38 made of an inorganic insulating material. The film thickness of the flattening film 36 made of an organic insulating material is, for example, approximately 2 μm to 3 μm, and is larger than the film thicknesses of the gate insulating film 34, the first interlayer insulating film 35, the second interlayer insulating film 37, and the third interlayer insulating film 38, which are made of an inorganic insulating material, in an order of magnitude higher. The surface of the array substrate 21 is flattened by the flattening film 36.

As illustrated in FIG. 5, the base coat film 33 is interposed between the glass substrate and the semiconductor portion 23D made of a semiconductor film. The base coat film 33 can suppress spread of impurities from the glass substrate into the semiconductor film. The gate insulating film 34 is interposed between the semiconductor portion 23D principally made of a semiconductor film and the gate electrode 23A made of the first metal film, and keeps both in an insulated state. The first interlayer insulating film 35 is interposed between the gate wiring 26 principally made of the first metal film and the source wiring 27 made of the second metal film, and keeps both in an insulated state. The flattening film 36 is interposed between the source wiring 27 principally made of the second metal film and the touch wiring 31 made of the third metal film, and keeps both in an insulated state. Since the source wiring 127 and the touch wiring 131 have a positional relationship to overlap each other via the flattening film 36, the disposition space occupied on the principal surface of the array substrate 21 can be reduced. As a result, it is preferable for improving the aperture ratio of the pixel or the like. The second interlayer insulating film 37 is interposed between the touch wiring 31 principally made of the third metal film and the common electrode 25 (touch electrode 30) made of the first transparent electrode film, and keeps both in an insulated state. The third interlayer insulating film 38 is interposed between the common electrode 25 principally made of the first transparent electrode film and the pixel electrode 24 principally made of the second transparent electrode film, and keeps both in an insulated state.

Subsequently, a cross-sectional configuration of the TFT 23 will be described with reference to FIG. 5. As illustrated in FIG. 5, the TFT 23 according to the present embodiment is a so-called top gate type, and a gate electrode 23A is disposed to overlap the semiconductor portion 23D on the upper layer side via the gate insulating film 34. A source contact hole CH1 is formed to open at a position that overlaps both the source electrode 23B and the semiconductor portion 23D of the gate insulating film 34 and the first interlayer insulating film 35. The source electrode 23B is coupled to the semiconductor portion 23D through the source contact hole CH1. A drain contact hole CH2 is formed to open at a position that overlaps both the drain electrode 23C and the semiconductor portion 23D of the gate insulating film 34 and the first interlayer insulating film 35. The drain electrode 23C is coupled to the semiconductor portion 23D through the drain contact hole CH2.

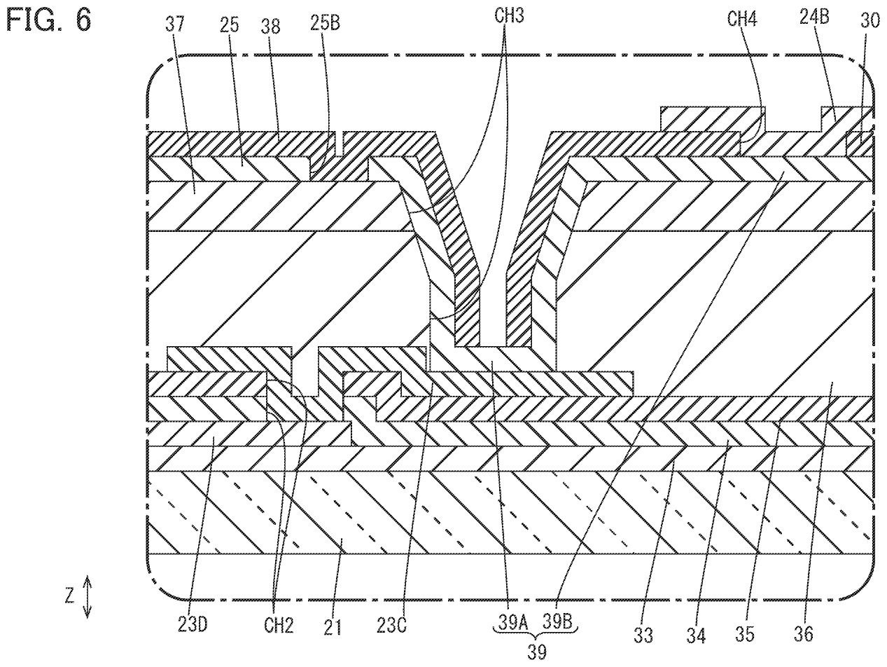

Next, a coupling structure between the drain electrode 23C and the pixel electrode 24 will be described in detail with reference to FIGS. 3 and 6. FIG. 6 is an enlarged cross-sectional view of the coupling structure between the drain electrode 23C and the pixel electrode 24 in FIG. 5. As illustrated in FIG. 6, the drain electrode 23C and the pixel electrode 24 are coupled via the first intermediate electrode 39 made of the first transparent electrode film. As illustrated in FIG. 3, the first intermediate electrode 39 has a horizontally long rectangular shape extending along the X-axis direction in a plan view. As illustrated in FIGS. 3 and 6, the first intermediate electrode 39 is disposed over a part of the drain electrode 23C (a part that does not overlap the semiconductor portion 23D) and the contact portion 24B of the pixel electrode 24. The first intermediate electrode 39 includes a first overlapping portion 39A that overlaps the drain electrode 23C and a second overlapping portion 39B that overlaps the contact portion 24B of the pixel electrode 24. Among these, the second overlapping portion 39B is a part of the first intermediate electrode 39 that does not overlap the entire area of drain electrode 23C. The first overlapping portion 39A does not overlap the contact portion 24B of the pixel electrode 24.

In the flattening film 36 and the second interlayer insulating film 37, as illustrated in FIG. 6, a first pixel contact hole (first contact hole) CH3 is formed to open at a position that overlaps both the drain electrode 23C and the first overlapping portion 39A. The first overlapping portion 39A is coupled to the drain electrode 23C through the first pixel contact hole CH3. In the third interlayer insulating film 38, the second pixel contact hole (second contact hole) CH4 is formed to open at a position that overlaps both the second overlapping portion 39B and the contact portion 24B of the pixel electrode 24. The contact portion 24B of the pixel electrode 24 is coupled to the second overlapping portion 39B through the second pixel contact hole CH4. As described above, the contact portion 24B of the pixel electrode 24 is coupled to the drain electrode 23C via the first intermediate electrode 39. Therefore, as compared with the case where the contact portion of the pixel electrode is directly coupled to the drain electrode, the level difference generated at the contact portion 24B of the pixel electrode 24 is reduced, and thus the coupling reliability is improved.

Here, as illustrated in FIGS. 3 and 6, the drain electrode 23C and the pixel electrode 24 have a positional relationship in which the drain electrode 23C and the pixel electrode 24 do not partially overlap each other, as described above. On the other hand, the first intermediate electrode 39 includes the first overlapping portion 39A that overlaps the drain electrode 23C and is coupled to the drain electrode 23C through the first pixel contact hole CH3; and the first overlapping portion 39B that overlaps the contact portion 24B of the pixel electrode 24 and is coupled to the contact portion 24B of the pixel electrode 24 through the second pixel contact hole CH4. That is, the first pixel contact hole CH3 and the second pixel contact hole CH4 have a positional relationship in which the first pixel contact hole CH3 and the second pixel contact hole CH4 do not overlap each other. Specifically, the first pixel contact hole CH3 and the second pixel contact hole CH4 are disposed at a position at an interval in the X-axis direction. In this manner, unlike in the related art, the second pixel contact hole CH4 is not provided in the third interlayer insulating film 38 in the first pixel contact hole CH3. Thereby the reliability that the second pixel contact hole CH4 will be appropriately formed in the third interlayer insulating film 38 is improved. Specifically, a level difference is unlikely to occur at the opening edge of the second pixel contact hole CH4 in the third interlayer insulating film 38, and then a film break is unlikely to occur in the contact portion 24B of the pixel electrode 24. Further, a situation in which the second pixel contact hole CH4 is not formed in the third interlayer insulating film 38 is unlikely to occur. As a result, it is possible to improve the coupling reliability between the first intermediate electrode 39 and the pixel electrode 24. By improving the coupling reliability between the TFT 23 and the pixel electrode 24, a defect that causes a poor display in the pixel electrode 24 is unlikely to occur.

As illustrated in FIG. 6, the first intermediate electrode 39 described above includes a part of the first transparent electrode film different from the common electrode 25. That is, when manufacturing the array substrate 21, the common electrode 25 and the first intermediate electrode 39 are collectively provided in the process of patterning the first transparent electrode film. The common electrode 25 is provided with a first opening portion 25B that surrounds the first intermediate electrode 39 in order to avoid a short circuit with the first intermediate electrode 39 made of the common first transparent electrode film. The first opening portion 25B has a horizontally long rectangular shape that has a size larger than the outer shape of the first intermediate electrode 39. As described above, since the first intermediate electrode 39 is disposed in the first opening portion 25B which is the non-formation range of the common electrode 25, the first intermediate electrode 39 can be configured by the first transparent electrode film that is common to the common electrode 25 while suppressing a short circuit with the common electrode 25. As illustrated in FIG. 5, a slit 25C is provided at a position that overlaps the touch wiring 31 in a plan view, in the common electrode 25. Since the parasitic capacitance that can occur between the touch wiring 31 and the touch electrode 30 to which the touch wiring 31 is not coupled is reduced by the slit 25C, the position detection sensitivity is improved.

As illustrated in FIG. 6, the total thickness of the flattening film 36 and the second interlayer insulating film 37 having the first pixel contact hole CH3 is larger than the film thickness of the third interlayer insulating film 38 having the second pixel contact hole CH4. In this manner, the flatness at the surface of the second interlayer insulating film 37 positioned on the upper layer side of the flattening film 36 and the second interlayer insulating film 37 is higher than the flatness at the surface of the third interlayer insulating film 38. As a result, the flatness of the second overlapping portion 39B of the first intermediate electrode 39 disposed at a position not overlapping the first pixel contact hole CH3 on the upper layer side of the second interlayer insulating film 37 is ensured, and thus the coupling reliability with the contact portion 24B of the pixel electrode 24 is further improved.

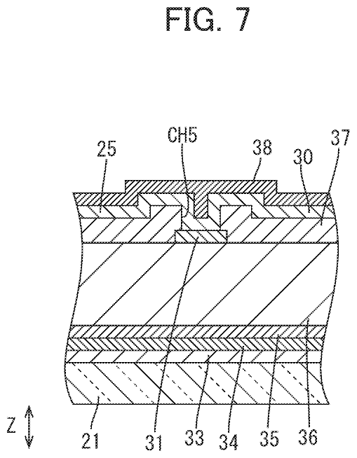

Next, a coupling structure between the touch electrode 30 (common electrode 25) and the touch wiring 31 will be described with reference to FIG. 7. FIG. 7 is a cross-sectional view illustrating the coupling structure between the touch electrode 30 and the touch wiring 31 on the array substrate 21. As illustrated in FIG. 7, a touch contact hole (third contact hole) CH5 is formed to open at a position that overlaps both the touch electrode 30 and the touch wiring 31 to be coupled to each other in the second interlayer insulating film 37. The overlapping part of the touch wiring 31 with the touch electrode 30 may be configured by, for example, a branch portion protruding along the X-axis direction from the body portion of the touch wiring 31 extending along the Y-axis direction. In addition to this, for example, the slits 25C provided in the touch electrode 30 may be set to a length that does not overlap the entire length of the touch wiring 31, the plurality of slits 25C may be disposed side by side at intervals in the Y-axis direction, and a part of the touch electrode 30 (a part positioned between two slits 25C arranged in the Y-axis direction) may be configured to overlap the touch wiring 31. Regardless, the touch electrode 30 is coupled to the touch wiring 31 to be coupled through the touch contact hole CH5.

The present embodiment has the above-described structure, and subsequently, a method for manufacturing the liquid crystal panel 10 will be described. The method for manufacturing the liquid crystal panel 10 includes a counter substrate manufacturing process (CF substrate manufacturing process) of manufacturing the counter substrate 20; an array substrate manufacturing process of manufacturing the array substrate 21; and a bonding process of bonding the manufactured counter substrate 20 and array substrate 21. Hereinafter, an array substrate manufacturing process of these will be described.

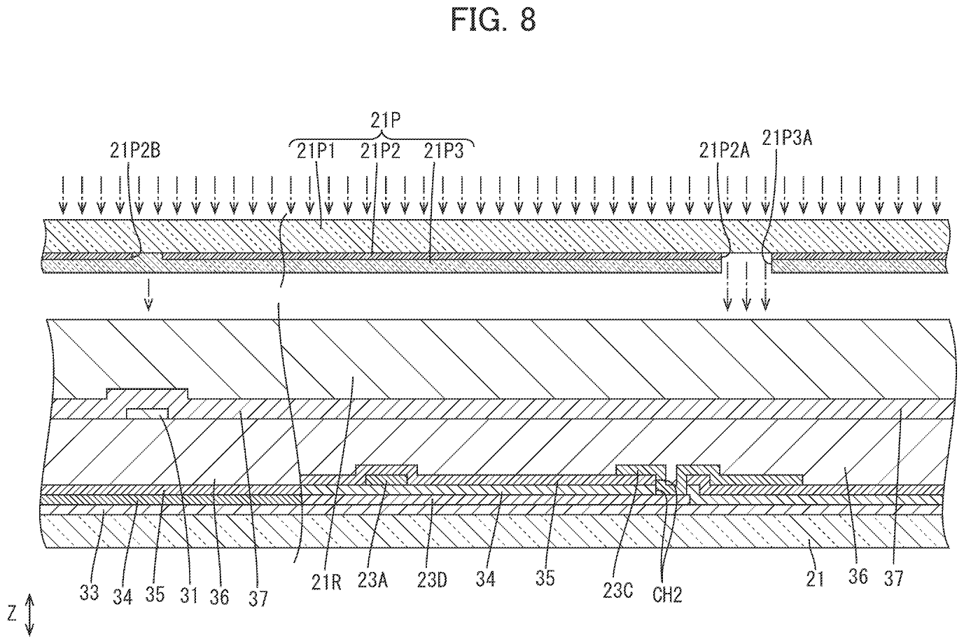

The array substrate manufacturing process includes a first process of forming a base coat film 33; a second process of forming and patterning a semiconductor film; a third process of forming the gate insulating film 34; a fourth process of forming and patterning the first metal film; a fifth process of forming and patterning the first interlayer insulating film 35; a sixth process of forming and patterning the second metal film; a seventh process of forming the flattening film 36; an eighth process of forming and patterning the third metal film; a ninth process of forming and patterning the second interlayer insulating film 37; a tenth process of forming and patterning the first transparent electrode film; an eleventh process of forming and patterning the third interlayer insulating film 38; a twelfth process of forming and patterning the second transparent electrode film; and a thirteenth process of forming the alignment film and performing the alignment process. Among these, the ninth process will be principally described in detail with reference to FIGS. 8 to 10. In FIGS. 8 to 10, the cross-sectional configuration of FIG. 6 (drain electrode 23C and the like) and the cross-sectional configuration of FIG. 7 (touch wiring 31 and the like) are illustrated adjacent to each other, and specifically, the cross-sectional configuration of FIG. 6 shown on the right side of FIGS. 8 to 10, and the cross-sectional configuration of FIG. 7 shown on the left side of FIGS. 8 to 10, are described.

The word “patterning” described above means processing of the film based on a general photolithography method. Specifically, a photoresist film is formed on a film to be processed, the photoresist film is exposed by an exposure device via a photomask having a predetermined pattern and then the photoresist film is developed, etching is performed via the developed photoresist film, and accordingly, processing of the film to be processed, that is, patterning is performed.

After the flattening film 36 is formed through the seventh process, when the eighth process is performed, the touch wiring 31 and the like made of the third metal film are provided. In the subsequent ninth process, as illustrated in FIG. 8, the second interlayer insulating film 37 and the photoresist film 21R are continuously formed in a solid shape on the upper layer side of the flattening film 36 and the third metal film. Thereafter, the photoresist film 21R is exposed using an exposure device and the photomask 21P (exposure process). The photoresist film 21R used in the ninth process is made of a positive photosensitive resist material. Here, the photomask 21P will be described. The photomask 21P includes a transparent base material 21P1 having sufficiently high light-transmitting properties; a light shielding film 21P2 formed on the principal surface of the base material 21P1; and a semi-transmissive film 21P3 formed on the principal surface of the base material 21P1 and partially laminated on the light shielding film 21P2. That is, the photomask 21P is a so-called halftone mask. The light shielding film 21P2 shields the exposure light from the light source of the exposure device, and the transmittance of the exposure light is substantially 0%. The semi-transmissive film 21P3 transmits exposure light from the light source of the exposure device at a predetermined transmittance. The semi-transmissive film 21P3 has a higher transmittance of the exposure light than the transmittance of the exposure light of the light shielding film 21P2, and the transmittance of the exposure light of the semi-transmissive film 21P3 is, for example, approximately 10% to 70%.

As illustrated in FIG. 8, the light shielding film 21P2 is disposed in a substantially solid shape in the display area AA, and has a first opening 21P2A at a position not overlapping the semiconductor portion 23D (drain contact hole CH2) of the drain electrode 23C. The light shielding film 21P2 has a second opening 21P2B at a position overlapping a part of the touch wiring 31. The semi-transmissive film 21P3 is disposed in a substantially solid shape in the display area AA, and has a third opening 21P3A at a position overlapping the first opening 21P2A of the light shielding film 21P2. The semi-transmissive film 21P3 is disposed to overlap the second opening 21P2B of the light shielding film 21P2. That is, the semi-transmissive film 21P3 is disposed in a range that does not overlap the first opening 21P2A. The photomask 21P is a light shielding area where the formation range of the light shielding film 21P2 blocks light, the formation range of the first opening 21P2A and the third opening 21P3A (non-formation range of the semi-transmissive film 21P3) is a transmissive area that transmits light, and the formation range of the second opening 21P2B is a semi-transmissive area that semi-transmits light. The amount of transmitted light through the semi-transmissive area is smaller than the amount of transmitted light through the transmissive area.

In the ninth process, when the exposure light emitted from the light source of the exposure device is emitted to the photoresist film 21R via the photomask 21P having the configuration described above, in the photoresist film 21R, a range overlapping the light shielding film 21P2 is not exposed, a range overlapping the first opening 21P2A and the third opening 21P3A, and a range overlapping the second opening 21P2B are respectively exposed. The range of the photoresist film 21R that overlaps the first opening 21P2A and the third opening 21P3A is exposed over the entire depth. In the photoresist film 21R, the exposure amount of a range overlapping the second opening 21P2B is smaller than that of a range overlapping the first opening 21P2A, and thus the upper part is exposed but the lower part is not substantially exposed.

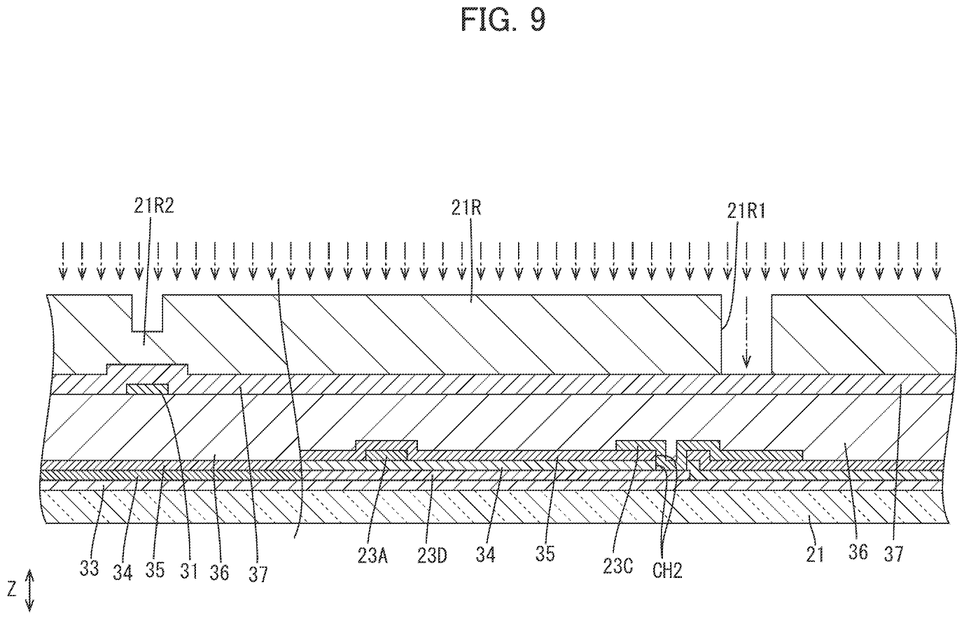

When the development is performed subsequent to the exposure, as illustrated in FIG. 9, the exposed part of the photoresist film 21R is removed by the thickness corresponding to the exposure amount (development process). In the photoresist film 21R, the range overlapping the first opening 21P2A and the third opening 21P3A is removed over the entire depth, but in the range overlapping with the second opening 21P2B, the upper part is removed and the lower part remains. On the other hand, the non-exposed part of the photoresist film 21R remains without being removed. As described above, the patterning of the photoresist film 21R using the photomask 21P is performed. The patterned photoresist film 21R has a fourth opening 21R1 formed over the entire depth and a thin film portion 21R2 having a smaller film thickness than that of a non-exposed part. The fourth opening 21R1 is disposed at a position that does not overlap the semiconductor portion 23D (drain contact hole CH2) in the drain electrode 23C. The thin film portion 21R2 is disposed at a position overlapping a part of the touch wiring 31.

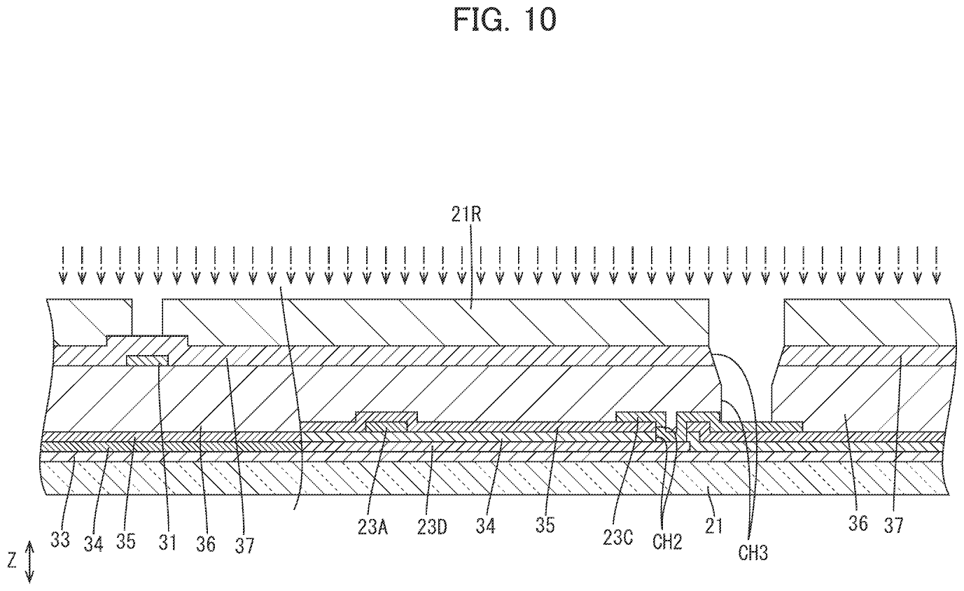

In the ninth process, as illustrated in FIG. 9, the flattening film 36 and the second interlayer insulating film 37 are collectively etched using the photoresist film 21R as a mask (first etching process). As a result, in the flattening film 36 and the second interlayer insulating film 37, a part that overlaps the fourth opening 21R1 is selectively removed since the part is exposed without being covered with the photoresist film 21R (non-exposed part and thin film portion 21R2), and a part that does not overlap the fourth opening 21R1 selectively remains since the part is covered with the photoresist film 21R and is not exposed (refer to FIG. 10). As a result, on the flattening film 36 and the second interlayer insulating film 37, the first pixel contact hole CH3 is formed to open in a communicating manner. A part of the drain electrode 23C is exposed by the first pixel contact hole CH3.

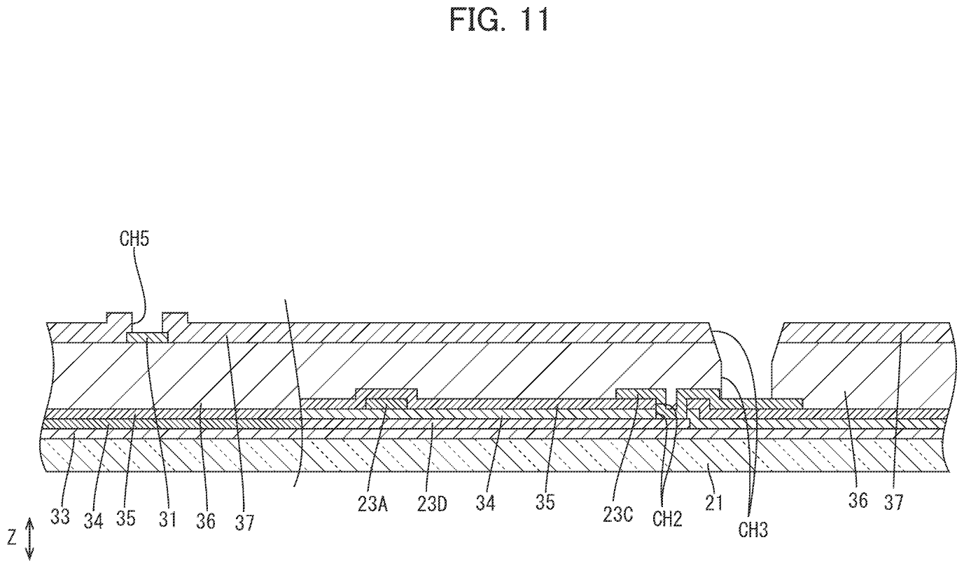

After etching the flattening film 36 and the second interlayer insulating film 37 as described above, the photoresist film 21R is ashed, and the thin film portion 21R2 is removed as illustrated in FIG. 10 (ashing process). Thereafter, the second interlayer insulating film 37 is etched using the remaining photoresist film 21R (non-exposed part) as a mask (second etching process). As a result, as illustrated in FIG. 11, in the second interlayer insulating film 37, the exposed part is selectively removed without being covered with the photoresist film 21R, and the part that is covered with the photoresist film 21R and not exposed selectively remains. As a result, the touch contact hole CH5 is formed to open in the second interlayer insulating film 37. A part of the touch wiring 31 is exposed by the touch contact hole CH5.

As described above, in the ninth process, since a method of exposing and developing the photoresist film 21R using the photomask 21P which is a halftone mask is adopted, the first pixel contact hole CH3 and the touch contact hole CH5 can be provided in one process.

As described above, the array substrate 21 of the present embodiment includes the drain electrode (first electrode) 23C made of the second metal film (first conductive film); the flattening film 36 and the second interlayer insulating film 37, which are first insulating films disposed on the upper layer side of the drain electrode 23C; the first intermediate electrode (second electrode) 39 made of the first transparent electrode film (second conductive film) disposed on the upper layer side of the flattening film 36 and the second interlayer insulating film 37, which are first insulating films; the third interlayer insulating film (second insulating film) 38 disposed on the upper layer side of the first intermediate electrode 39; and the pixel electrode (third electrode) 24 made of the third conductive film disposed on the upper layer side of the third interlayer insulating film 38, at least a part of the pixel electrode 24 does not overlap the drain electrode 23C, the first intermediate electrode 39 includes the first overlapping portion 39A that overlaps the drain electrode 23C, and the second overlapping portion 39B that does not overlap the drain electrode 23C and overlaps the pixel electrode 24, the flattening film 36 and the second interlayer insulating film 37, which are the first insulating films, have the first pixel contact hole (first contact hole) CH3 disposed at a position overlapping the drain electrode 23C and the first overlapping portion 39A, and the third interlayer insulating film 38 has the second pixel contact hole (second contact hole) CH4 disposed at a position overlapping the second overlapping portion 39B and the pixel electrode 24.

The first overlapping portion 39A of the first intermediate electrode 39 is coupled to the drain electrode 23C through the first pixel contact hole CH3 of the flattening film 36 and the second interlayer insulating film 37, which are the first insulating films. The pixel electrode 24 is coupled to the second overlapping portion 39B of the first intermediate electrode 39 through the second pixel contact hole CH4 of the third interlayer insulating film 38. As described above, the pixel electrode 24 is coupled to the drain electrode 23C via the first intermediate electrode 39. Therefore, as compared with the case where the pixel electrode is directly coupled to the drain electrode, the level difference generated in the pixel electrode 24 is reduced, and thus the coupling reliability is improved. Here, the drain electrode 23C and the pixel electrode 24 have a positional relationship in which the drain electrode 23C and the pixel electrode 24 does not partially overlap each other. On the other hand, the first intermediate electrode 39 includes the first overlapping portion 39A that overlaps the drain electrode 23C and is coupled to the drain electrode 23C through the first pixel contact hole CH3; and the second overlapping portion 39B that overlaps the pixel electrode 24 and is coupled to the pixel electrode 24 through the second pixel contact hole CH4. That is, the first pixel contact hole CH3 and the second pixel contact hole CH4 have a positional relationship in which the first pixel contact hole CH3 and the second pixel contact hole CH4 do not overlap each other. In this manner, unlike in the related art, the second pixel contact hole CH4 is not provided in the third interlayer insulating film 38 in the first pixel contact hole CH3. Thereby the reliability that the second pixel contact hole CH4 will be appropriately formed in the third interlayer insulating film 38 is improved. As a result, it is possible to improve the coupling reliability between the first intermediate electrode 39 and the pixel electrode 24.

The flattening film 36 and the second interlayer insulating film 37, which are the first insulating films, have a larger film thickness than that of the third interlayer insulating film 38. In this manner, the flatness on the surfaces of the flattening film 36 and the second interlayer insulating film 37, which are the first insulating films, is higher than the flatness on the surface of the third interlayer insulating film 38. As a result, the flatness of the second overlapping portion 39B of the first intermediate electrode 39 disposed at a position not overlapping the first pixel contact hole CH3 on the upper layer side of the flattening film 36 and the second interlayer insulating film 37, which are first insulating films, is ensured, and the coupling reliability with the pixel electrode 24 is further improved.

In addition, the TFT (switching element) 23, the pixel electrode 24 coupled to the TFT 23, and the common electrode 25 disposed to overlap the pixel electrode 24 are provided, the TFT 23 includes the drain electrode 23C, the common electrode 25 is made of a part of the first transparent electrode film different from the first intermediate electrode 39 to have the first opening portion 25B surrounding the first intermediate electrode 39, and the pixel electrode 24 is the third electrode. When the TFT 23 is driven, an image signal is supplied from the drain electrode 23C to the pixel electrode 24, which is the third electrode, via the first intermediate electrode 39, and the pixel electrode 24 is charged. An electric field corresponding to the potential difference is generated between the charged pixel electrode 24 and the common electrode 25. By improving the coupling reliability between the TFT 23 and the pixel electrode 24, a defect that causes a poor display in the pixel electrode 24 is unlikely to occur. Here, the common electrode 25 has the first opening portion 25B surrounding the first intermediate electrode 39 in order to suppress a short circuit with the pixel electrode 24. Since the first intermediate electrode 39 is disposed in the first opening portion 25B which is a non-formation range of the common electrode 25, the first intermediate electrode 39 can be formed using a part of the first transparent electrode film different from the common electrode 25. As described above, the common electrode 25 and the first intermediate electrode 39 can be formed using the common first transparent electrode film.

In addition, the first insulating film is formed by laminating the flattening film (lower insulating film) 36 and the second interlayer insulating film (upper insulating film) 37, and includes the touch wiring (first wiring) 31 made of the third metal film (fourth conductive film) positioned on the upper layer side of the flattening film 36 and on the lower layer side of the second interlayer insulating film 37, at least a part of the touch wiring 31 is disposed to overlap the common electrode 25, and the second interlayer insulating film 37 has the touch contact hole (third contact hole) CH5 disposed at a position overlapping the common electrode 25 and the touch wiring 31. The common electrode 25 is coupled to the touch wiring 31 through the touch contact hole CH5 in the second interlayer insulating film 37. The common electrode 25 has a potential based on a signal supplied by the touch wiring 31. Here, while the first pixel contact hole CH3 is provided over the second interlayer insulating film 37 and the flattening film 36, the touch contact hole CH5 is provided in the second interlayer insulating film 37 and is not provided in the flattening film 36. According to such a configuration, during manufacturing, for example, when a method is adopted in which the flattening film 36, the second interlayer insulating film 37, and the photoresist film 21R are sequentially formed, and then the photoresist film 21R is exposed and developed using a halftone mask or a gray-tone mask, it becomes possible to provide the first pixel contact hole CH3 and the touch contact hole CH5 in one process.

The liquid crystal panel (display) 10 of the present embodiment includes the above-described array substrate 21 and the counter substrate 20 disposed to face the array substrate 21. According to the liquid crystal panel 10 having such a configuration, since the coupling reliability between the first intermediate electrode 39 and the pixel electrode 24 is improved, excellent display quality can be obtained.

### Embodiment 2

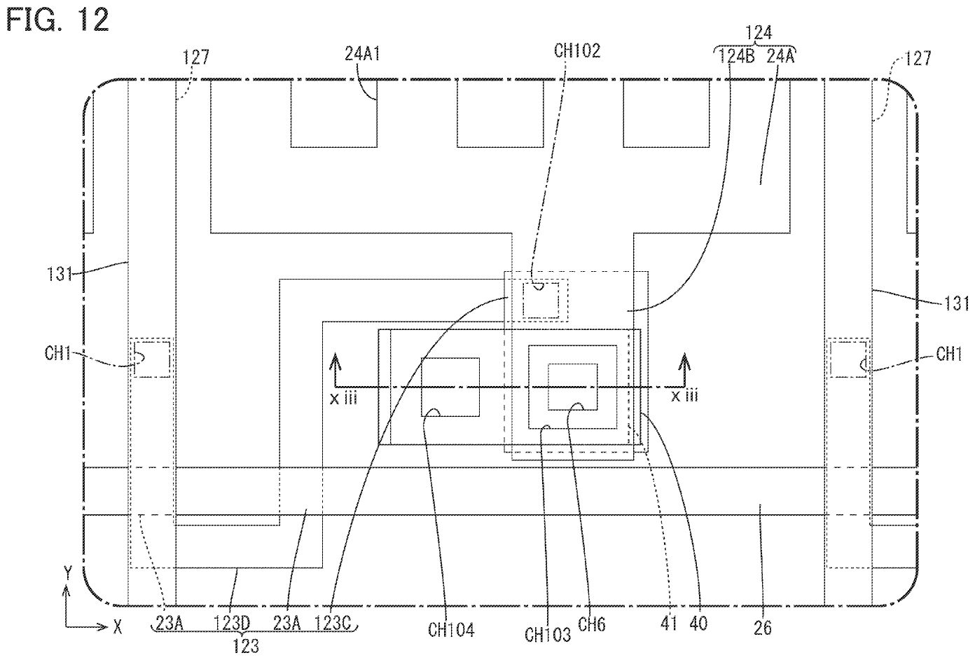

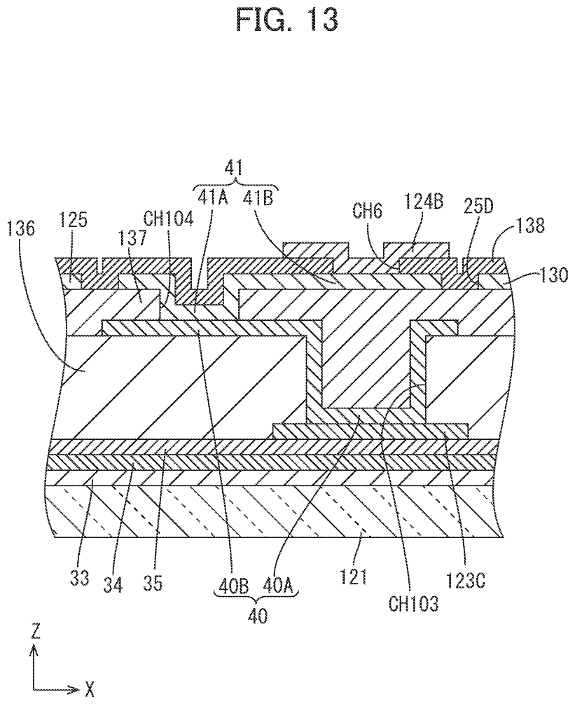

Embodiment 2 will be described with reference to FIG. 12 or 13. Embodiment 2 shows a case where the coupling structure between a drain electrode 123C and a pixel electrode 124 is changed. Duplicate descriptions of structure, action, and effect similar to those of Embodiment 1 described above will be omitted.

In the array substrate 121 according to the present embodiment, as illustrated in FIG. 12, most of the drain electrode 123C is disposed to overlap a contact portion 124B of the pixel electrode (fourth electrode) 124. The other end portion of the semiconductor portion 123D is disposed to overlap a part of the drain electrode 123C and a part of the contact portion 124B. A drain contact hole CH102 is disposed at a position overlapping both the other end portion of the semiconductor portion 123D and the drain electrode 123C. The array substrate 121 according to the present embodiment has a second intermediate electrode (second electrode) 40 and a third intermediate electrode (third electrode) 41 instead of the first intermediate electrode 39 (refer to FIG. 6) described in Embodiment 1. That is, in the present embodiment, a part of the drain electrode 123C (lower part in FIG. 12) is coupled to the contact portion 124B of the pixel electrode 124 via the second intermediate electrode 40 and the third intermediate electrode 41.

As illustrated in FIG. 12, the second intermediate electrode 40 has a horizontally long rectangular shape extending along the X-axis direction in a plan view. As illustrated in FIGS. 12 and 13, the second intermediate electrode 40 is made of identical third metal film (second conductive film) as the touch wiring 131. In other words, the second intermediate electrode 40 is made of a part of the third metal film different from the touch wiring 131, and when manufacturing the array substrate 121, in the process of patterning the third metal film, the touch wiring 131 and the second intermediate electrodes 40 are collectively provided. A part of the second intermediate electrode 40 is disposed to overlap a part of the drain electrode 123C and a part of the contact portion 124B (a part that does not overlap the semiconductor portion 123D) in a plane. A part of the second intermediate electrode 40 that overlaps a part of the drain electrode 123C and a part of the contact portion 124B is a first overlapping portion 40A. A part of the second intermediate electrode 40 other than the first overlapping portion 40A (a part that does not overlap the entire area of the drain electrode 123C) is a second overlapping portion 40B that overlaps the third intermediate electrode 41 described later in a plane. The second intermediate electrode 40 is disposed not to overlap the semiconductor portion 123D over the entire area.

As illustrated in FIG. 12, the third intermediate electrode 41 has a horizontally long rectangular shape extending along the X-axis direction in a plan view. The third intermediate electrode 41 is disposed to mostly overlap the second intermediate electrode 40 in a plane view. As illustrated in FIGS. 12 and 13, the third intermediate electrode 41 is made of identical first transparent electrode film (third conductive film) as the common electrode 125. In other words, the third intermediate electrode 41 is made of a part of the first transparent electrode film different from the common electrode 125 (touch electrode 130), and when manufacturing the array substrate 121, in the process of patterning the first transparent electrode film, the common electrode 125 and the third intermediate electrode 41 are collectively provided. Similarly to the second intermediate electrode 40, the third intermediate electrode 41 is disposed to overlap a part of the drain electrode 123C and a part of the contact portion 124B (a part that does not overlap the semiconductor portion 123D) in a plane. In the third intermediate electrode 41, a part that overlaps the second overlapping portion 40B of the second intermediate electrode 40 (a part that does not overlap the entire area of the drain electrode 123C) is defined as the third overlapping portion 41A. In the third intermediate electrode 41, a part that overlaps the first overlapping portion 40A of the second intermediate electrode 40 (a part that overlaps a part of the drain electrode 123C and a part of the contact portion 124B) is a fourth overlapping portion 41B. The fourth overlapping portion 41B does not overlap the second overlapping portion 40B. The third intermediate electrode 41 is disposed not to overlap the semiconductor portion 123D over the entire area.

As illustrated in FIG. 13, the common electrode 125 is provided with a second opening portion 25D surrounding the third intermediate electrode 41 in order to avoid a short circuit with the third intermediate electrode 41 made of the common first transparent electrode film. The second opening portion 25D has a horizontally long rectangular shape that has a size larger than the outer shape of the third intermediate electrode 41. As described above, since the third intermediate electrode 41 is disposed in the second opening portion 25D which is the non-formation range of the common electrode 125, the third intermediate electrode 41 can be configured by the first transparent electrode film that is common to the common electrode 125 while suppressing a short circuit with the common electrode 125.

In the flattening film (first insulating film) 136, as illustrated in FIG. 13, a first pixel contact hole (first contact hole) CH103 is formed to open at a position that overlaps both the drain electrode 123C and the first overlapping portion 40A of the second intermediate electrode 40. The first overlapping portion 40A is coupled to the drain electrode 123C through the first pixel contact hole CH103. In a second interlayer insulating film (second insulating film) 137, a second pixel contact hole (second contact hole) CH104 is formed to open at a position overlapping both the second overlapping portion 40B of the second intermediate electrode 40 and the third overlapping portion 41A of the third intermediate electrode 41. The third overlapping portion 41A is coupled to the second overlapping portion 40B through the second pixel contact hole CH104. In a third interlayer insulating film (third insulating film) 138, a third pixel contact hole (fourth contact hole) CH6 is formed to open at a position overlapping both the fourth overlapping portion 41B of the third intermediate electrode 41 and the contact portion 124B of the pixel electrode 124. The contact portion 124B of the pixel electrode 124 is coupled to the fourth overlapping portion 41B through the third pixel contact hole CH6. As described above, the contact portion 124B of the pixel electrode 124 is coupled to the drain electrode 123C via the second intermediate electrode 40 and the third intermediate electrode 41. Therefore, as compared with the case where the pixel electrode is directly coupled to the second intermediate electrode, the level difference generated in the pixel electrode 124 is reduced, and thus the coupling reliability is improved. Therefore, as compared with the case where the contact portion of the pixel electrode is directly coupled to the drain electrode, the level difference generated at the contact portion 124B of the pixel electrode 124 is reduced, and thus the coupling reliability is improved.

Moreover, as illustrated in FIG. 13, the second interlayer insulating film 137 according to the present embodiment has a larger film thickness than that of the third interlayer insulating film 138. The material used for the second interlayer insulating film 137 may be an inorganic insulating material similar to that in Embodiment 1 described above, and may be an organic insulating material similar to that for the flattening film 136. In this manner, the flatness on the surfaces of the second interlayer insulating film 137 is higher than the flatness on the surface of the third interlayer insulating film 138. As a result, the flatness of the fourth overlapping portion 41B of the third intermediate electrode 41 disposed at a position not overlapping the second pixel contact hole CH104 on the upper layer side of the second interlayer insulating film 137 is ensured, and thus the coupling reliability with the contact portion 124B of the pixel electrode 124 is further improved.

Here, in the present embodiment, as illustrated in FIGS. 12 and 13, the fourth overlapping portion 41B of the third intermediate electrode 41 is disposed to overlap the first overlapping portion 40A of the second intermediate electrode 40 in a plan view. That is, a part of the drain electrode 123C and a part of the contact portion 124B of the pixel electrode 124 overlap each other, and a positional relationship is achieved in which the first pixel contact hole CH103 and the third pixel contact hole CH6 overlap each other. As compared with the case where the drain electrode and the contact portion of the pixel electrode are disposed not to overlap each other (the case where each pixel contact hole CH6, CH103, and CH104 is disposed not to overlap each other), the arrangement space occupied on the principal surface of the array substrate 121 can be reduced. As a result, it is preferable for improving the aperture ratio of the pixel or the like. Moreover, as described above, since the film thickness of the second interlayer insulating film 137 is larger than the film thickness of the third interlayer insulating film 138, due to the first pixel contact hole CH103, unevenness is less likely to occur on the surface of the second interlayer insulating film 137. Therefore, even when the fourth overlapping portion 41B has a relationship overlapping the first pixel contact hole CH103, the flatness of the fourth overlapping portion 41B is well ensured, and coupling reliability with the contact portion 124B of the pixel electrode 124 is well kept.

Incidentally, as illustrated in FIG. 12, the touch wiring 131 is disposed to overlap the source wiring 127 via the flattening film 136, and thus the touch wiring 131 is not formed around the first pixel contact hole CH103, the second pixel contact hole CH104, and the touch contact hole CH5. Since the second intermediate electrode 40 is disposed in a non-formation range of the touch wiring 131, the second intermediate electrode 40 can be formed using a part of the third metal film different from the touch wiring 131. As described above, the touch wiring 131 and the second intermediate electrode 40 can be formed using the common third metal film.

In addition, as illustrated in FIG. 13, the common electrode 125 includes the second opening portion 25D surrounding the third intermediate electrode 41 in order to suppress a short circuit with the contact portion 124B of the pixel electrode 124. Since the third intermediate electrode 41 is disposed in the second opening portion 25D which is a non-formation range of the common electrode 125, the third intermediate electrode 41 can be formed using a part of the first transparent electrode film different from the common electrode 125. As described above, the common electrode 125 and the third intermediate electrode 41 can be formed using the common first transparent electrode film.

As described above, according to the present embodiment, the third interlayer insulating film (third insulating film) 138 disposed on the upper layer side of the third intermediate electrode (third electrode) 41, and the pixel electrode (fourth electrode) 124 made of the second transparent electrode film (fifth conductive film) disposed on the upper layer side of the third interlayer insulating film 138 are provided, at least a part of the pixel electrode 124 does not overlap the second overlapping portion 40B, the third intermediate electrode 41 includes the third overlapping portion 41A that overlaps the second overlapping portion 40B and the fourth overlapping portion 41B that does not overlap the second overlapping portion 40B and overlaps the pixel electrode 124, and the third interlayer insulating film 138 has the third pixel contact hole (fourth contact hole) CH6 disposed at a position overlapping the pixel electrode 124 and the fourth overlapping portion 41B. The pixel electrode 124 is coupled to the fourth overlapping portion 41B of the third intermediate electrode 41 through the third pixel contact hole CH6 of the third interlayer insulating film 138. As described above, since the pixel electrode 124 is coupled to the drain electrode (first electrode) 123C via the third intermediate electrode 41 and the second intermediate electrode (second electrode) 40, as compared with the case where the pixel electrode is directly coupled to the second intermediate electrode, the level difference generated in the pixel electrode 124 is reduced, and thus the coupling reliability is improved.

The second interlayer insulating film (second insulating film) 137 has a larger film thickness than the third interlayer insulating film 138. In this manner, the flatness on the surfaces of the second interlayer insulating film 137 is higher than the flatness on the surface of the third interlayer insulating film 138. As a result, the flatness of the fourth overlapping portion 41B of the third intermediate electrode 41 disposed at a position not overlapping the second pixel contact hole (second contact hole) CH104 on the upper layer side of the second interlayer insulating film 137 is ensured, and thus the coupling reliability with the pixel electrode 124 is further improved.

The fourth overlapping portion 41B is disposed to overlap the first overlapping portion 40A. In this manner, the drain electrode 123C and the pixel electrode 124 overlap each other, and a positional relationship is achieved in which the first pixel contact hole CH103 and the third pixel contact hole CH6 overlap each other. As compared with the case where the drain electrode and the pixel electrode are disposed not to overlap each other, the space can be reduced, which is suitable for improving the aperture ratio and the like. In addition, since the film thickness of the second interlayer insulating film 137 is larger than the film thickness of the third interlayer insulating film 138, due to the first pixel contact hole CH103, unevenness is less likely to occur on the surface of the second interlayer insulating film 137. Therefore, even when the fourth overlapping portion 41B has a relationship overlapping the first pixel contact hole CH103, the flatness of the fourth overlapping portion 41B is well ensured, and coupling reliability with the pixel electrode 124 is well kept.

The TFT 123, the source wiring (second wiring) 127 coupled to the TFT 123, the pixel electrode 124 coupled to the TFT 123, the common electrode 125 disposed to overlap the pixel electrode 124, and the touch wiring (third wiring) 131 coupled to the common electrode 125 are provided, the TFT 123 has the drain electrode 123C, the source wiring 127 is made of a part of the second metal film different from the drain electrode 123C, the touch wiring 131 is made of a part of the third metal film (second conductive film) different from the second intermediate electrode 40, and is disposed to overlap the source wiring 127, the common electrode 125 is made of a part of the first transparent electrode film different from the third intermediate electrode 41 to have a second opening portion 25D surrounding the third intermediate electrode 41, and the pixel electrode 124 is made of the fourth electrode. When the TFT 123 is driven, an image signal is supplied from the drain electrode 123C to the pixel electrode 124 which is the fourth electrode via the second intermediate electrode 40 and the third intermediate electrode 41, and the pixel electrode 124 is charged. The common electrode 125 has a potential based on a signal supplied by the touch wiring 131. An electric field corresponding to the potential difference is generated between the charged pixel electrode 124 and the common electrode 125. By improving the coupling reliability between the TFT 123 and the pixel electrode 124, a defect that causes a poor display in the pixel electrode 124 is unlikely to occur. Since the source wiring 127 and the touch wiring 131 have a positional relationship to overlap each other via the flattening film (first insulating film) 136, the space can be reduced, and thus the aperture ratio can be improved. Here, since the touch wiring 131 is disposed to overlap the source wiring 127, the touch wiring 131 is not formed around the first pixel contact hole CH103, the second pixel contact hole CH104, and the touch contact hole (third contact hole) CH5. Since the second intermediate electrode 40 is disposed in a non-formation range of the touch wiring 131, the second intermediate electrode 40 can be formed using a part of the third metal film different from the touch wiring 131. The common electrode 125 has the second opening portion 25D surrounding the third intermediate electrode 41 in order to suppress a short circuit with the pixel electrode 124. Since the third intermediate electrode 41 is disposed in the second opening portion 25D which is a non-formation range of the common electrode 125, the third intermediate electrode 41 can be formed using a part of the first transparent electrode film different from the common electrode 125. As described above, the touch wiring 131 and the second intermediate electrode 40 can be formed using the common third metal film, and the common electrode 125 and the third intermediate electrode 41 can be formed using the common first transparent electrode film.

### Other Embodiments

The technique disclosed in the present specification is not limited to the embodiments described by the above description and drawings, and for example, the following embodiments are also included in the technical scope.

(1) In the configuration described in Embodiment 1, a part of the contact portion 24B of the pixel electrode 24 may be disposed to overlap the drain electrode 23C in a plan view.

(2) In the configuration described in Embodiment 2, the contact portion 124B of the pixel electrode 124 and the fourth overlapping portion 41B of the third intermediate electrode 41 may be disposed not to overlap the drain electrode 123C in a plan view. In this case, the pixel contact holes CH6, CH103, and CH104 are disposed not to overlap each other.

(3) The film thickness of the second interlayer insulating film 37 may be approximately the same as the film thicknesses of the other insulating films 33, 34, 35, and 38 made of an inorganic insulating material.

(4) In the configuration described in Embodiment 1, it is also possible to omit the touch wiring 31 and have the common electrode 25 in a non-divided structure. In that case, the third metal film and the second interlayer insulating film 37 can be omitted from various films provided on the array substrate 21. In a case where the third metal film and the second interlayer insulating film 37 are omitted, the “second insulating film” is configured to include only the flattening film 36. The “common electrode having a non-divided structure” described above is the common electrode 25 that does not have the partition opening portion 25A and extends in a solid shape at least in the display area AA.

(5) The liquid crystal panel 10 may not have a touch panel function. In that case, it is also possible to omit the touch wirings 31 and 131 and have the common electrodes 25 and 125 in a non-divided structure, and the touch wirings 31 and 131 may remain as a “common wiring” while the common electrodes 25 and 125 have a divided structure. The “common wiring” supplies a common potential signal exclusively to each division electrode constituting the common electrodes 25 and 125.

(6) The specific planar shapes of the semiconductor portions 23D and 123D can be appropriately changed. The disposition of the source electrode 23B can be appropriately changed as the planar shapes of the semiconductor portions 23D and 123D are changed. For example, it is also possible to provide a part branched from the body parts of the source wirings 27 and 127 and to use the branch portion as the source electrode 23B.

(7) As the photomask 21P, it is also possible to use a gray-tone mask in addition to the halftone mask.

(8) The photoresist film 21R may have a negative type as well as the positive type.

(9) It is also possible to omit the gate circuit unit 13. In that case, a gate driver having the same function as that of the gate circuit unit 13 may be mounted on the array substrates 21 and 121. It is also possible to provide the gate circuit unit 13 only on one side of the array substrates 21 and 121.

(10) The configuration of the TFTs 23 and 123 may be a bottom gate type, a double gate type, or the like, in addition to the top gate type.

(11) The material of the semiconductor film may be an amorphous semiconductor material, an oxide semiconductor material, or the like.

(12) The touch panel pattern may be a mutual capacitance method in addition to the self capacitance method.

(13) The color filter 28 may be provided on the array substrates 21 and 121. In that case, both the pixel electrodes 24 and 124 and the color filter 28 are provided on the array substrates 21 and 121, and components of the pixel are not provided on the counter substrate 20.

(14) The planar shape of the liquid crystal panel 10 may be a vertically long rectangle, a square, a circle, a semicircle, an oval, an ellipse, a trapezoid, or the like.

(15) The liquid crystal panel 10 may be a reflective type or a semi-transmissive type.

(16) In addition to the liquid crystal panel 10, a display panel (such as an organic electroluminescence (EL) display panel) or an electrophoresis display panel (EPD) may be used.

(17) In the technique described in Embodiment 1, it is also possible to manufacture the array substrate 21 without using a halftone mask or a gray-tone mask. For example, by patterning the flattening film 36 that is formed in the seventh process included in the array substrate manufacturing process, a part of the first pixel contact hole CH3 may be formed to open in the flattening film 36, and by patterning the second interlayer insulating film 37 formed in the ninth process, the remaining part of the first pixel contact hole CH3 and the touch contact hole CH5 may be formed in the second interlayer insulating film 37, respectively.

The present disclosure contains subject matter related to that disclosed in Japanese Priority Patent Application JP 2023-029354 filed in the Japan Patent Office on Feb. 28, 2023, the entire contents of which are hereby incorporated by reference.

It should be understood by those skilled in the art that various modifications, combinations, sub-combinations and alterations may occur depending on design requirements and other factors insofar as they are within the scope of the appended claims or the equivalents thereof.

What is claimed is:

1. An array substrate comprising:
a first electrode made of a first conductive film;
a first insulating film disposed on an upper layer side of the first electrode;
a second electrode made of a second conductive film disposed on an upper layer side of the first insulating film;
a second insulating film disposed on an upper layer side of the second electrode; and
a third electrode made of a third conductive film disposed on an upper layer side of the second insulating film, wherein
at least a part of the third electrode does not overlap the first electrode,
the second electrode has a first overlapping portion that overlaps the first electrode and a second overlapping portion that does not overlap the first electrode and overlaps the third electrode,
the first insulating film has a first contact hole disposed at a position overlapping the first electrode and the first overlapping portion, and
the second insulating film has a second contact hole disposed at a position overlapping the second overlapping portion and the third electrode.

2. The array substrate according to claim 1, wherein
the first insulating film has a larger film thickness than that of the second insulating film.

3. The array substrate according to claim 1, further comprising:
a switching element;
a pixel electrode coupled to the switching element; and
a common electrode disposed to overlap the pixel electrode, wherein
the switching element has the first electrode,
the common electrode is made of a part of the second conductive film different from the second electrode to have a first opening portion surrounding the second electrode, and the pixel electrode is the third electrode.

4. The array substrate according to claim 3, wherein
the first insulating film is formed by laminating a lower insulating film and an upper insulating film,
a first wiring made of a fourth conductive film positioned on an upper layer side of the lower insulating film and a lower layer side of the upper insulating film, is provided,
at least a part of the first wiring is disposed to overlap the common electrode, and
the upper insulating film includes a third contact hole disposed at a position overlapping the common electrode and the first wiring.

5. The array substrate according to claim 1, further comprising:
a third insulating film disposed on an upper layer side of the third electrode; and
a fourth electrode made of a fifth conductive film disposed on an upper layer side of the third insulating film, wherein
at least a part of the fourth electrode does not overlap the second overlapping portion,
the third electrode includes a third overlapping portion that overlaps the second overlapping portion and a fourth overlapping portion that does not overlap the second overlapping portion and overlaps the fourth electrode, and
the third insulating film includes a fourth contact hole disposed at a position overlapping the fourth electrode and the fourth overlapping portion.

6. The array substrate according to claim 5, wherein
the second insulating film has a larger film thickness than that of the third insulating film.

7. The array substrate according to claim 6, wherein
the fourth overlapping portion is disposed to overlap the first overlapping portion.

8. The array substrate according to claim 5, further comprising:
a switching element;
a second wiring coupled to the switching element;
a pixel electrode coupled to the switching element;
a common electrode disposed to overlap the pixel electrode; and
a third wiring coupled to the common electrode, wherein
the switching element has the first electrode,
the second wiring is made of a part of the first conductive film different from the first electrode,
the third wiring is made of a part of the second conductive film different from the second electrode, and is disposed to overlap the second wiring,
the common electrode is made of a part of the third conductive film different from the third electrode to have a second opening portion surrounding the third electrode, and

9. A display comprising:
the array substrate according to claim 1; and
a counter substrate disposed to face the array substrate.
